(19) United States
(12) Patent Application Publication
(10) Pub. No.: US 2010/0244860 A1
(43) Pub. Date: Sep. 30, 2010

(54) CAPACITIVE ANTI-PINCH MEANS AND METHOD FOR OPERATING AN ANTI-PINCH MEANS

(76) Inventors: Karl Wisspeintner, Ortenburg (DE); Norbert Reindl, Furstenzell (DE)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 12/675,661

(22) PCT Filed: Sep. 1, 2008
(86) PCT No.: PCT/DE2008/001436

§ 371 Date: May 26, 2010

(30) Foreign Application Priority Data
Aug. 30, 2007 (DE) 10 2007 041 241.1

(51) Int. Cl. G01R 27/26

(52) U.S. Cl. 324/679

(57) ABSTRACT

A capacitive anti-pinch means with a first electrode (2) and a second electrode (3), wherein the first electrode (2) and the second electrode (3) form the electrodes of one sensor, is, as regards a measurement which is independent of a ground potential (M1), characterized in that the first electrode (2) can be fed a first potential (U_{ref+}), in that the second electrode (3) can be fed a second potential (U_{ref-}), wherein the second potential (U_{ref-}) is different from the first potential (U_{ref+}), and in that said means are equipped with evaluation electronics (5) which determine the difference between the first potential (U_{ref+}) and the second potential (U_{ref-}) and determine the capacitance (C_{Sensor}) of the sensor from said difference. A corresponding method for operating the anti-pinch means (1) is disclosed.

The invention concerns a capacitive auto reverse with a first electrode and a second electrode, the first electrode and the second electrode forming the electrodes of a sensor. The invention also concerns a method for operation of corresponding auto reverse.

Arrangements and methods used for auto reverse on doors, hatches, sunroofs, convertible tops and the like are sufficiently known from practice. Optical, contact and capacitive methods are mostly used here. For applications in industry DE 40 06 119 A1 and EP 1 474 582 A1 can be referred to as examples, for applications in the automotive field, DE 43 29 535 A1, DE 103 10 066 B3, DE 197 20 713 C1, DE 199 13 879 C1, DE 102 20 725 C1, DE 103 05 342 B4 and EP 1 154 110 B1.

In a contact auto reverse it is essential for detection of obstacles that direct contact occur between the sensor and the object to be recognized. Versions with one or two conductors are then known. For example, a sensor is described in EP 1 474 582 A1, which recognizes obstacles by contact with a wire-shaped element. The sensor known from DE 43 29 535 A1 operates with two areas made of electrically conducting plastics and/or electrical conductors introduced to plastic. An ohmic contact is formed by compression of the plastic areas or conductors, which is used to detect an obstacle. An invariable problem in contact auto reverse is that contact must occur in principle. This is precisely what is not desired, if jamming of human limbs is to be prevented.

In contrast to contact methods, contactless detection can occur in a capacitive auto reverse. The capacitance of a sensor is measured in this case. The capacitance of a sensor changes on approach of an object with dielectric properties, which is used as measurement effect. It is known that a defined reference potential must be present for capacitance measurement, to which the measurement refers. The usual reference potential for the measurement is ground. Very many of the known methods use an individual electrode and the mass of surrounding elements of the sensor environment connected to ground. Methods are also known in which two electrodes are explicitly used. These include, among others, the already mentioned DE 40 06 119 A1, DE 103 10 066 B3 or

EP 1 154 110 B1. A sensor electrode and a ground electrode are then used, the ground electrode being designed as actual electrode and connected to ground, as the name very clearly indicates.

It is a shortcoming in the known methods with two electrodes that ground is not clearly defined in all parts not connected firmly to the ground. For example, in a vehicle the ground can amount to potential differences of several volts, depending on the installation location, which leads to significant measurement errors. Thus, a defined electrical connection to the auto body is not guaranteed in a door or trunk lid of a vehicle, since lubricant in the door hinge or corrosion of metal surfaces reduces contact. This situation is similar in elevators. There, moving door leaves can only be brought to a defined ground potential in demanding fashion via ground cables.

The underlying task of the present invention is therefore to provide a capacitive auto reverse of the type just mentioned in which the indicated problems with reference to ground potential are eliminated. A corresponding method is given.

The aforementioned task is solved according to the invention by the features of claim 1. Accordingly the auto reverse at issue is modified so that the first electrode (2) can be fed with a first potential (U_{ref+}), that the second electrode (3) can be fed with a second potential (U_{ref-}), the second potential (U_{ref-}) being different from the first potential (U_{ref+}) and that evaluation electronics (5) is provided, which determines the difference between the first potential (U_{ref+}) and the second potential (U_{ref-}) and determines the capacitance (C_{Sensor}) of the sensor from it.

With respect to the method the aforementioned task is solved by the features of claim 8. Accordingly the method is characterized by the fact that first electrode (2) is supplied a first potential (U_{ref+}), that the second electrode (3) is supplied a second potential (U_{ref-}), the second potential (U_{ref-}) being different from the first potential (U_{ref+}), that the difference between the first potential (U_{ref+}) and the second potential (U_{ref-}) is determined and that the capacitance (C_{Sensor}) of the sensor is determined from it.

According to the invention it was initially recognized that a defined ground potential can be completely dispensed with during determination of the capacitance of a sensor. Instead it is sufficient if the difference in potentials at which the electrodes of the sensor are found, can be clearly determined. The first electrode is therefore brought according to the invention to the first potential and the second electrode to the second potential. The first and second potential must refer to a common ground. However, the potential of ground (and herein lies a major advantage) can be unknown. From knowledge of the two potentials referred to an unknown potential level, the difference between the first potential and the second potential can be determined instead and from it the capacitance C_{Sensor} of the sensor formed from the two electrodes. Since the capacitance of the sensor changes on approach of an object, the presence of an object in the measurement range can be detected from the capacitance measurement. Methods known from practice are available for this purpose. For example, charge measurement and time measurement can be mentioned for this purpose.

Supply of the first electrode with the first potential U_{ref+} is advantageously achieved via a first voltage source. This first voltage source can be connected to the voltage source via a switch. The electrode can be raised to a defined potential with it and capacitance measurement carried out after opening of the switch. The switch can be formed in a variety of ways known from practice. However, the switch will advantageously be a semiconductor component to simplify control with electronics.

The same applies for the second electrode, which can be brought to the second potential U_{ref-} by means of a second voltage source. Here again a switch between the electrode and voltage source serves to separate the capacitive measurement.

An obstacle in capacitance measurement has proven to be that the electrodes of the sensor have a parasitic offset capacitance C_{Offset P} and C_{Offset N} relative to ground of the sensor (ground M1) which is unknown or can even change during operation. It is again pointed out that the ground M1 can generally deviate for the already mentioned reasons from the ground of evaluation electronics (ground M2) and therefore cannot be used for measurement. The evaluation electronics therefore establishes the corresponding potentials relative to ground M2.

It is therefore proposed for improvement of the capacitance measurement that the offset capacitances C_{Offset P} and C_{Offset N} be compensated by parallel charge supply, in which defined potentials U_{comp+} and U_{comp-} are connected to the electrodes of the sensor. A situation can be achieved by this in which the measurement window used for measurement is shifted into the region of evaluation where the sensitivity of the sensor is higher. The compensation potential U_{comp} can then be positive or negative so that the compensation potential increases or reduces the potential to which an electrode was brought. The measurement window can therefore be shifted independently of the offset capacitance C_{Offset} into the optimal range.

The actual measurement always occurs in a constant capacitance window, which can have different capacitances or potential relative to ground. A ground-free measurement is therefore possible and a change in ground potential has no effect on the measurement result.

In practice the capacitance of the sensor is very large, for example, in the range of 100 pF. Approach of a hand, on the other hand, changes the capacitance only by a few (for example, 5) pF so that the sensitivity, i.e., the useful signal, would be relatively limited in comparison with the total capacitance of the arrangement. Parallel supply of compensation potentials can therefore also be used to compensate the high base capacitance of the sensor and therefore achieve a high resolution measurement window. The measurement window can also be shifted into range favorable for evaluation. The sensor then has a constant sensitivity despite fluctuations of the offset capacitances.

To establish the compensation potentials U_{comp+} and U_{comp-} calibration measurements could be conducted after installation. A measurement series conducted once on a sample environment could also be conducted and transferred to corresponding installation situations. As an alternative, adjustment of the compensation potentials could be conducted so that the measured capacitance value assumes a desired value or value range during measurement without an object in the measurement range. The compensation potentials U_{comp+} and U_{comp-} can then assume a value identical in amount. However, this is not absolutely necessary. Instead, the potentials could also differ in amount.

At least one additional voltage source can preferably be provided to supply the compensation potentials. These compensation potentials can be added to the first potential and the second potential and make compensation available.

With respect to further flexibility of the auto reverse the potential released by the additional voltage source can be controllable. Depending on the desired boundary conditions the potential of an electrode could therefore be raised or reduced. In particular, a reaction to varying offset capacitances can be achieved by a controllable voltage source.

As an alternative or in addition, the voltage sources could be switched by means of a switch. A positive and a negative compensation potential could therefore be provided for each electrode, which is switched to the electrode as required.

Preferably the one or more additional voltage sources could be controllable by the evaluation electronics. The evaluation electronics could also assume switching on or switching off of the compensation potentials to the electrodes. The evaluation electronics could therefore select the potentials lying on the electrodes so that the most optimal possible measurement could be achieved.

The evaluation electronics has symmetric inputs with respect to simplified evaluation.

In an advantageous modification drift compensation can be carried out by tracking the potentials U_{ref+} and U_{ref-} and the compensation potentials U_{comp+} and U_{comp-}. Individual or all potentials can then be varied. Drift of capacitances can occur, for example, if the distance between wires changes. The change can develop relatively briefly because of temperature changes, for example, caused by heating and a resulting shape change of a sealing profile during solar radiation. Thawing or condensation of water on a sealing profile can also alter the capacitance, since water has a relatively high dielectric constant. However, over a longer period the capacitances can also change because of aging effect in the employed material, for example, by shrinkage of plastics. These types of drift can alter both the offset capacitances and the sensor capacitances in an undesired way. By tracking the reference potentials U_{ref+} and U_{ref-} and the compensation potentials U_{comp+} and U_{comp-} this drift can be allowed for.

The rate of drift compensation can be freely set. By changing the rate or by using different measurement frequencies disorders can also be deliberately masked by placing the measurement frequency in a range not affected by the disturbance. For recognition of obstacles, especially persons, very rapid detection is required. A measurement cycle is then in the range of a few milliseconds. Temperature changes, on the other hand, occur in the range of seconds or minutes. Aging effects extend over months or years. On the other hand, electromagnetic disturbances are found in the range of fractions of milliseconds. By appropriate choice of the measurement frequency or by multifrequency methods a largely disturbance-free operation can deliberately be achieved.

The solution according to the invention is largely insensitive to disturbance in the form of electromagnetic interference because of its symmetrical configuration. Since both wires of the sensor are mounted at limited spacing from each other, for example, a few millimeters, disturbances act in the same manner on both wires through external electromagnetic fields. The potentials of the wires relative to ground M2 are shifted. However, by symmetric layout of the sensor and because of ground-independent measurement these disturbances act in the same manner on both electrodes. Systematic common mode rejection is achieved on this account, for which reason the measurement is largely independent of external disturbances. If the sensor were designed with only one wire, whose capacitance is measured relative to ground, or with two wires, one of which lies at ground, the disturbances would not be eliminated and would therefore adversely affect the measurement.

There are different possibilities for configuring and modifying the instructions of the present invention advantageously. On the one hand, the claims subordinate to claim 1 and claim 8 and, on the other hand, the following explanation of a preferred practical example of the invention with reference to the drawing can be referred to. In conjunction with the explanation of a preferred practical example of the invention by means of a drawing generally preferred embodiments and modifications of the instructions are also explained. In the drawing

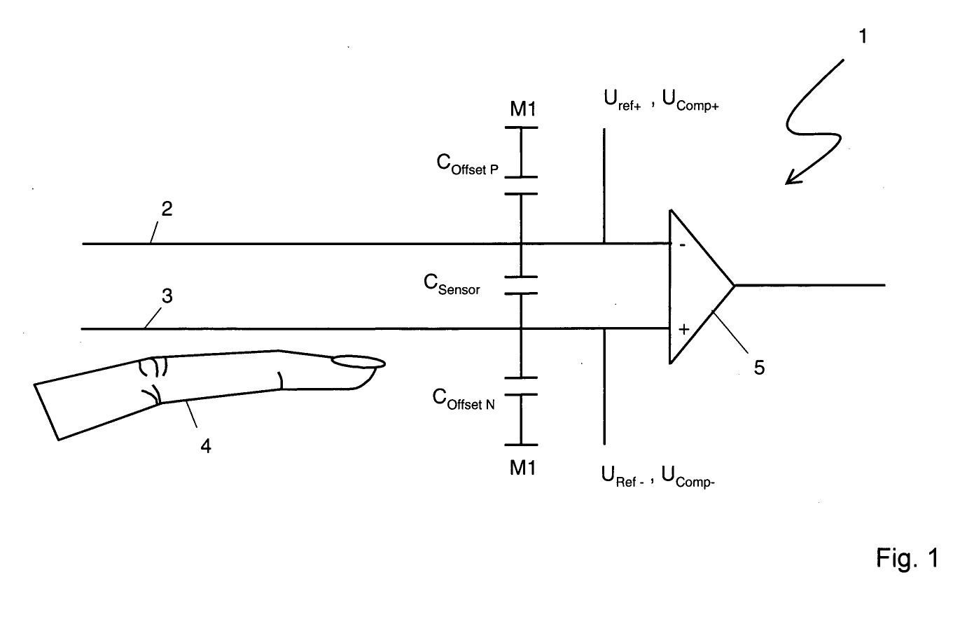

FIG. 1 shows a schematic view of the basic structure of an auto reverse according to the invention and

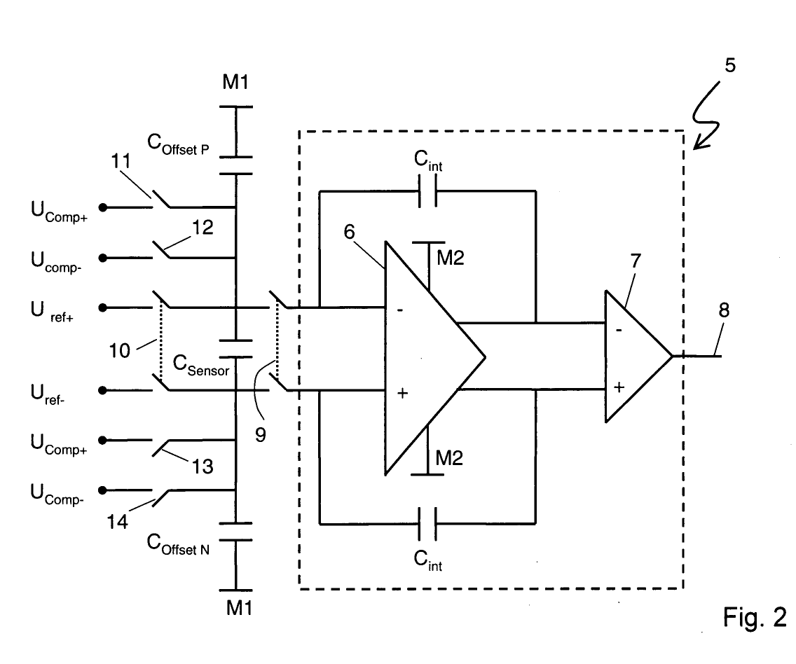

FIG. 2 shows a circuit diagram of an evaluation electronics designed as an amplifier circuit.

FIG. 1 shows the essential design of a capacitive auto reverse 1 according to the invention. The two sensor electrodes—the first electrode 2 and the second electrode 3—each consist of a wire, the wires running parallel to each other at limited spacing and extending along the closure edge of a door or window to be secured. The wires can be integrated in a sealing rubber of a window pane in a vehicle door. Both electrodes 2, 3 form a capacitance C_{Sensor}. The parasitic capacitances relative to ground M1 generated by the structure or its surroundings are given as C_{Offset P} and C_{offset N}. If an object, say, a finger 4, approaches the sensor arrangement 1, the capacitance C_{Sensor} changes. Measurement of the capacitance or its change occurs with an evaluation electronics 5 which is designed as an amplifier circuit indicated by the stylized operating amplifier. Evaluation occurs in known fashion, for example, by charge measurement or by time measurement.

FIG. 2 shows a circuit diagram of the evaluation electronics 5 in detail. The core of the evaluation electronics 5 is an operating amplifier 6, with whose inverting input the first electrode 2 is connected and with whose non-inverting input the second electrode 3 is connected. The operating amplifier 6 produces a different signal which is fed to a second operating amplifier 7. This generates an output signal 8 that leaves the evaluation electronics 5. A capacitance Cᵢₙₜ serves as wiring for the operating amplifier 6, each of which back couples and output of the operating amplifier 6 to the inverting and non-inverting input. The evaluation electronics 5 is connected to ground M2.

Two switches 9 that synchronously switch and connect the electrodes 2, 3 to the operating amplifier 6 are arranged between the electrodes 2, 3 and the operating amplifier 6. To describe the parasitic effects the capacitance C_{Offset P} and C_{Offset N} are again shown, each of which lies between one of the connections of capacitance C_{Sensor} and ground M1. At the connection point between the first electrode 2 and capacitance C_{Offset P} the first potential U_{ref+} and the two compensation potentials U_{comp+} and U_{comp-} can be switched by means of switches 10, 11 and 12. At the connection point between the second electrode 3 and capacitance C_{offset N} the second potential U_{ref-} and the two compensation potentials U_{comp+} and U_{comp-} can be switched by means of switches 10, 13 and 14. Switch 10 is then laid out so that it can switch both lines synchronously.

For compensation of the offset capacitances C_{Offset P}, C_{Offset N} they are already compensated during installation by applying compensation voltages U_{comp+} and U_{comp-} so that the measurement window on the first operating amplifier 6 lies in a favorable range for the actual capacitance measurement. The compensation voltages U_{comp+} and U_{comp-} can each be polarized, according to the requirements, either positively or negatively relative to ground M2.

For measurement of capacitance C_{Sensor} of the sensor the charge source is used in known fashion by applying, in a first step, reference voltages U_{ref+} and U_{ref-} via switch 10 to the sensor capacitance C_{Sensor}. After the charging process, the reference voltages are separated again by opening switch 10. In the second step a charge on the sensor capacitance C_{Sensor} is measured by switch 9 with the operating amplifier 6 by integration over the capacitances Cᵢₙₜ. The arrangement is symmetric up to the output of the operating amplifier 6. The difference signal from the operating amplifier 6 is then amplified in the operating amplifier 7 and fed as voltage via output 8. The signal can then be further conveyed for further processing, for example, to the control electronics of the window lift, the elevator door or the like.

The general part of the description and the accompanying patent claims are referred to relative to other advantageous embodiments of the device according to the invention to avoid repetitions.

Finally, it is explicitly pointed out that the practical examples of the device according to the invention just described merely serve to explain the claimed instruction but not restrict it to the practical examples.

### LIST OF REFERENCE NUMBERS

1 Auto reverse
2 First electrode
3 Second electrode
4 Finger
5 Evaluation electronics
6 Operating amplifier
7 Operating amplifier
8 Output signal
9 Switch
10 Switch
11 Switch
12 Switch
13 Switch
14 Switch

1.-15. (canceled)

16. A capacitive auto reverse means, comprising:
a first electrode and a second electrode, the first electrode and the second electrode forming the electrodes of a sensor, wherein the first electrode is fed with a first potential (U_{ref+}), the second electrode (3) is fed with a second potential (U_{ref-}), the second potential (U_{ref-}) being different from the first potential (U_{ref+}), and wherein evaluation electronics is provided, which determines the difference between the first potential (U_{ref+}) and second potential (U_{ref-}) and determines the capacitance (C_{Sensor}) of the sensor from said difference.

17. The auto reverse means according to claim 16, wherein the first electrode is connected to the first potential (U_{ref+}) for feed via a switch to a first voltage source and the second electrode is connected for feed to the second potential (U_{ref-}) via a switch to a second voltage source.

18. The auto reverse means according to claim 16, wherein at least one additional voltage source is provided that provides a compensation potential (U_{comp+}, U_{comp-}).

19. The auto reverse means according to claim 18, wherein the potential (U_{comp+}, U_{comp-}) produced by the additional voltage source is controllable.

20. The auto reverse means according to claim 18, wherein the additional voltage source can be switched by means of a switch.

21. The auto reverse means according to claim 19, wherein the additional voltage source is controllable or switchable via the evaluation electronics.

22. The auto reverse means according to claim 16, wherein the evaluation electronics has symmetric inputs.

23. A method for operation of an auto reverse with a first electrode and a second electrode, in which the first electrode and the second electrode form electrodes of a sensor, said method comprising:
supplying the first electrode with a first potential (U_{ref+}), and supplying the second electrode with a second potential (U_{ref-}), the second potential (U_{ref-}) being different from the first potential (U_{ref+}), wherein the difference between the first potential (U_{ref+}) and the second potential (U_{ref-}) is determined and wherein a capacitance (C_{Sensor}) of the sensor is determined from said difference.

24. The method according to claim 23, wherein at least one compensation potential (U_{comp+} and U_{comp-}) is generated by means of at least one additional voltage source.

25. The method according to claim 24, wherein an offset capacitance (C_{Offset P}, C_{Offset N}) is compensated by means of a compensation potential (U_{comp+}, U_{comp-}).

26. The method according to claim 24, wherein a sensitivity of the sensor is controlled by means of compensation potential (U_{comp+}, U_{comp-}).

27. The method according to claim 24, wherein drift of the sensor is compensated by means of a compensation potential (U_{comp+}, U_{comp-}).

28. The method according to claim 24, wherein disturbances are compensated by means of a compensation potential (U_{comp+}, U_{comp-}).

29. The method according to claim 23, wherein the capacitance (C_{Sensor}) of the sensor is determined by means of charge measurement.

30. The method according to claim 23, wherein the capacitance (C_{Sensor}) of the sensor is determined with time measurement.
